(19) United States
(12) Patent Application Publication
(10) Pub. No.: US 2022/0157858 A1
(43) Pub. Date: May 19, 2022

(54) DISPLAY PANEL, PREPARATION METHOD THEREOF AND DISPLAY DEVICE

(71) Applicants: Chengdu BOE Optoelectronics Technology Co., Ltd., Chengdu (CN); BOE Technology Group Co., Ltd., Beijing (CN)

(72) Inventors: Hao Luo, Beijing (CN); Yin Deng, Beijing (CN); Dongmei Wei, Beijing (CN); Bo Wu, Beijing (CN)

(21) Appl. No.: 17/588,860

(22) Filed: Jan. 31, 2022

Related U.S. Application Data
(63) Continuation of application No. 16/976,611, filed on Aug. 28, 2020.

(51) Int. Cl. H01L 27/12; H01R 12/59; H05K 1/14; H01R 12/70

(52) U.S. Cl. CPC H01L 27/1244; H01L 27/1292; H01L 27/1262; H01R 12/7076; H01R 12/592; H05K 1/147; H01L 27/1218

(57) ABSTRACT

The application relates to the technical field of display, and discloses a display panel, a preparation method thereof and a display device. The display panel includes: a rigid base substrate; a flexible insulating layer having a first part and a second part, the first part being disposed on the base substrate, the second part exceeding a side edge of the base substrate; and an integrated circuit chip and a flexible printed circuit respectively bonded and connected with the second part of the flexible insulating layer.

### CROSS REFERENCE TO RELATED APPLICATIONS

The present application is a continuation of U.S. patent application Ser. No. 16/976,611 filed with USPTO on Aug. 28, 2020. The U.S. patent application Ser. No. 16/976,611 is a national phase entry under 35 U.S.C. § 371 of International Application No. PCT/CN2019/114889 filed with WIPO on Oct. 31, 2019.

### FIELD

The present application relates to the technical field of display, in particular to a display panel, a preparation method thereof and a display device.

### BACKGROUND

Now, mobile phones have entered an era of full screens, and all large mobile phone manufacturers are pursuing extreme full screens and a high screen-to-body ratio. A left narrow frame and a right narrow frame are mature, and an upper frame can be achieved through a bangs screen, a water drop screen or even a lifting camera. In the process of pursuing the full screens, the width of a lower frame becomes the maximum bottleneck limiting the improvement of the screen-to-body ratio. Therefore, how to realize an ultra-narrow lower frame is an urgent technical problem to be solved for current display panels.

### SUMMARY

The present application discloses a display panel, a preparation method thereof and a display device, which are configured to provide an ultra-narrow frame solution of a rigid display panel.

A display panel includes:

a base substrate which is rigid;

a flexible insulating layer including a first part and a second part, the first part being disposed on the base substrate, and the second part exceeding a side edge of the base substrate; and

an integrated circuit chip and a flexible printed circuit respectively bonded and connected with the second part of the flexible insulating layer.

Optionally, the flexible printed circuit is located on a side, away from the first part of the flexible insulating layer, of the integrated circuit chip.

Optionally, the base substrate includes a display region and a connecting region on a side of the display region.

A projection of the first part of the flexible insulating layer on the base substrate is in the connecting region, and the second part exceeds a side edge of the connecting region of the base substrate.

Optionally, a width of the connecting region in a direction away from the display region ranges from 200 μm to 400 μm; and a width of the first part in the direction away from the display region ranges from 200 μm to 300 μm.

Optionally, the display panel further includes a buffer layer disposed on a side, away from the base substrate, of the flexible insulating layer, and the buffer layer completely covers a surface of the side, away from the base substrate, of the flexible insulating layer.

Optionally, a projection of a part, arranged over the base substrate, of the buffer layer on the base substrate is in the connecting region.

Optionally, the display panel further includes a drive circuit disposed on a side, away from the base substrate, of the buffer layer.

Optionally, a material of the flexible insulating layer is polyimide; and a material of the base substrate is glass.

Optionally, the display panel further includes a color film substrate, and a side edge, close to the second part of the flexible insulating layer, of the color film substrate is aligned with the side edge of the base substrate.

Optionally, the second part of the flexible insulating layer is bent to a side, facing away from the first part of the flexible insulating layer, of the base substrate.

A display device includes any one of the above mentioned display panels.

Optionally, the display device further includes a circuit board located on a side, facing away from the first part of the flexible insulating layer, of the base substrate.

The second part of the flexible insulating layer is bent to the side, facing away from the first part of the flexible insulating layer, of the base substrate.

The integrated circuit chip is electrically connected with the circuit board.

A method for preparing a display panel includes:

providing a base substrate which is rigid, wherein the base substrate includes a first region and a second region on a side of the first region;

forming a flexible insulating layer on the base substrate, wherein the flexible insulating layer includes a first part on the first region and a second part on the second region;

bonding an integrated circuit chip and a flexible printed circuit on the second part of the flexible insulating layer respectively;

stripping the second part of the flexible insulating layer from the second region of the base substrate; and

cutting off the second region of the base substrate.

Optionally, the first region includes a display region and a connecting region, and the connecting region is located between the display region and the second region.

The forming the flexible insulating layer on the base substrate includes:

forming the flexible insulating layer on the connecting region and the second region of the base substrate.

Optionally, the forming the flexible insulating layer on the base substrate includes:

forming the flexible insulating layer on the base substrate in a silk-screen printing process.

Optionally, before bonding the integrated circuit chip and the flexible printed circuit on the second part of the flexible insulating layer, the method further includes:

forming a pattern of a drive circuit on the base substrate in an array process.

Optionally, before forming the pattern of the drive circuit on the base substrate in the array process, the method further includes:

forming a buffer layer on the flexible insulating layer, wherein a projection of the buffer layer on the base substrate encompasses a projection of the flexible insulating layer on the base substrate.

Optionally, the stripping the second part of the flexible insulating layer from the second region of the base substrate includes:

stripping the second part of the flexible insulating layer from the second region of the base substrate by adopting a laser lift off technology.

Optionally, the cutting off the second region of the base substrate includes:

cutting the base substrate along a boundary line between the first region and the second region from a side, away from the flexible insulating layer, of the base substrate, wherein a cutting depth is smaller than a thickness of the base substrate; and

separating the first region and the second region of the base substrate along the boundary line by external force.

Optionally, after cutting off the second region of the base substrate, the method further includes:

bending the second part of the flexible insulating layer to a side, facing away from the first part of the flexible insulating layer, of the base substrate for packaging.

### BRIEF DESCRIPTION OF THE DRAWINGS

FIG. 1 is a cross-sectional schematic diagram and a schematic top view of a display panel provided by an embodiment of the present application.

FIG. 2 is a partial cross-sectional structural schematic diagram of a display panel provided by another embodiment of the present disclosure.

FIG. 3 is a cross-sectional structural schematic diagram of a display panel provided by another embodiment of the present disclosure.

FIG. 4 is a cross-sectional structural schematic diagram of a display panel provided by another embodiment of the present disclosure.

FIGS. 5A to 5C are comparison cross-sectional structural schematic diagrams of a display panel provided by an embodiment of the present disclosure and two display panels in the related art.

FIG. 6 is a flow chart of a method for preparing a display panel provided by an embodiment of the present disclosure.

FIG. 7 is a cross-sectional schematic diagram and a schematic top view of a display panel provided by an embodiment of the present disclosure at a preparation stage.

FIG. 8 is a cross-sectional schematic diagram and a schematic top view of a display panel provided by an embodiment of the present disclosure at another preparation stage.

FIG. 9 is a schematic top view of a display panel provided by an embodiment of the present disclosure at another preparation stage.

FIG. 10 is a schematic top view of a display panel provided by an embodiment of the present disclosure at another preparation stage.

### DETAILED DESCRIPTION OF THE EMBODIMENTS

The technical solution in embodiments of the present disclosure will be described clearly and fully hereinafter in combination with the accompanying drawings in the embodiments of the present disclosure. It is apparent that the described embodiments are only part of the embodiments of the present disclosure, not all embodiments. Based on the embodiments in the present disclosure, all other embodiments obtained by those ordinarily skilled in the art without involving any inventive effort are within the scope of protection of the present disclosure.

As shown in FIGS. 1 to 4, embodiments of the present disclosure provides a display panel, including:

a rigid base substrate 1;

a flexible insulating layer 2, including a first part 21 and a second part 22, wherein the first part 21 is disposed on the base substrate 1, and the second part 22 exceeds a side edge of the base substrate 1; and

an integrated circuit chip (IC) 3 and a flexible printed circuit (FPC) 4 which are respectively bonded and connected with the second part 22 of the flexible insulating layer 2.

According to the above display panel, the flexible insulating layer 2 is disposed on the rigid base substrate 1, the first part 21 of the flexible insulating layer 2 is disposed on the base substrate 1, and the second part 22 extends a side edge of the base substrate 1 and is bonded with the IC 3 and the FPC 4. In a display cell preparation stage, the second part 22 of the flexible insulating layer 2 can be bent to a back surface of the base substrate 1 for packaging as shown in FIG. 5A, and a narrow frame of a display cell is thus realized. Specifically, as shown in FIG. 5A, since the flexible insulating layer 2 of the present application is directly deposited on the base substrate 1, a frame region of the base substrate 1 does not need to be bonded with neither the IC nor the FPC, and the frame of the display panel may be designed to be very narrow. Specifically, compared with a COF (chip on FPC) scheme of bonding an FPC 40 on a glass substrate 10 and bonding a chip on the FPC 40 as shown in FIG. 5B and a COG (chip on Glass) scheme of bonding a chip 30 and an FPC 40 on a glass substrate 10 as shown in FIG. 5C, the frame is narrower. Meanwhile, compared with the COF scheme, the display panel provided by the application can be realized only by adopting a COG bonding process and a simple flexible deposition process, the process is simple, the defect of COF resource shortage can be avoided, the yield loss problem caused by the COF bonding process can also be avoided, and the practicability is high. In addition, the display panel provided by the application can be simultaneously suitable for rigid organic light emitting displays (OLEDs) and rigid liquid crystal displays (LCDs), so that the rigid OLEDs and the rigid LCDs still have strong competitiveness in the era of full screens.

Specifically, as shown in FIGS. 1 to 4, both the IC 3 and the FPC 4 are disposed on the second part 22 of the flexible insulating layer 2 and distributed in an extending direction of the flexible insulating layer 2. Specifically, the FPC 4 is located on a side, away from the first part 21 of the flexible insulating layer 2, of the IC 3, that is, in the extending direction of the flexible insulating layer 2, the IC 3 is close to the first part 21 of the flexible insulating layer 2, and the FPC 4 is away from the first part 21 of the flexible insulating layer 2.

In some embodiments, a material of the flexible insulating layer 2 may be polyimide (PI); and a material of the base substrate 1 may be glass.

In some embodiments, the base substrate 1 includes a display region AA and a connecting region BB located on a side of the display region AA. A projection of the first part 21 of the flexible insulating layer 2 on the base substrate 1 is in the connecting region BB and the second part 22 extends a side edge of the connecting region BB of the base substrate 1. That is, there is no flexible insulating layer 2 on the display region AA of the base substrate 1, and the flexible insulating layer 2 is disposed only on a frame region (the connecting region BB) on a side of the display region AA and partially exceeds the frame region.

Furthermore, only simple signal wires are disposed on the flexible insulating layer 2, and pixels do not need to be prepared on the flexible insulating layer 2 like in the display region AA, so that the requirement for the surface of the flexible insulating layer 2 is not high, the requirement for a process of preparing the flexible insulating layer 2 on the base substrate 1 is simple, and the process can be realized through conventional silk-screen printing and other processes. Therefore, slit coating equipment in a flexible OLED preparation process does not need to be purchased, so that the cost of the scheme is greatly reduced.

Specifically, the above-mentioned ‘display region’ and ‘connecting region’ of the base substrate, and the later-referred ‘first region’ and ‘second region’ all refer to respective part structures of the base substrate in the extending direction, and do not represent a region range.

In some embodiments, when the display panel of the embodiment of the present application is applied to a mobile phone display cell, a width d of the connecting region BB in a direction away from the display region AA may be designed to be about 200 μm to 400 μm. The width is much smaller than a width (greater than 1 mm) of a bonding region of the COF. Further, a width of the first part 21 of the flexible insulating layer 2 in a direction away from the display region AA may be about 200 μm to 300 μm.

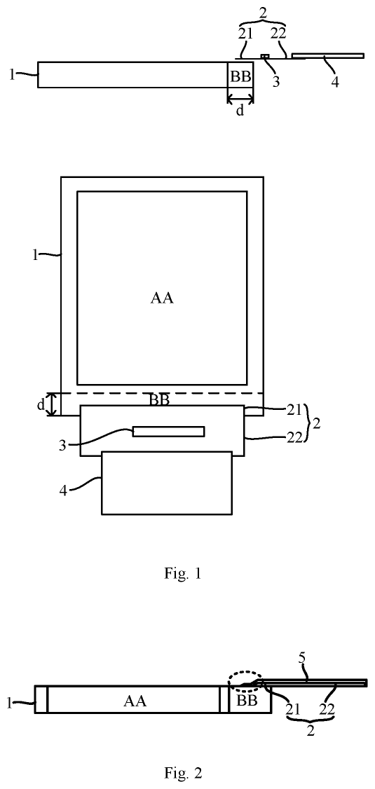

In some embodiments, as shown in FIG. 2, the display panel of an embodiment of the present application further includes a buffer layer 5 disposed on a side, away from the base substrate 1, of the flexible insulating layer 2, and the buffer layer 5 completely covers a surface of the side, away from the base substrate 1, of the flexible insulating layer 2.

Further, the display panel of some embodiments of the present application further includes a drive circuit disposed on a side, away from the base substrate 1, of the buffer layer 5.

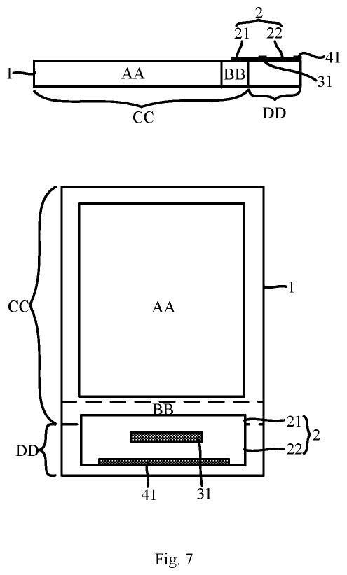

Specifically, the drive circuit in some embodiments of the present application includes all pattern structures required for implementing pixel driving, including pixel circuits within the display region AA, metal wires extending to the flexible insulating layer 2, connection terminals located on the second part 22 of the flexible insulating layer 2 and used for being bonded with the IC 3 and the FPC 4 or the like, for example, as shown in FIG. 7 and FIG. 10, a connection terminal 31 for being bonded with the IC 3 and a connection terminal 41 for being bonded with the FPC 4 are disposed on the second part 22 of the flexible insulating layer 2.

Specifically, the flexible insulating layer 2 has strong water absorption capacity, the buffer layer 5 is disposed before the drive circuit (including the metal wires) is formed, the flexible insulating layer 2 and a drive circuit layer are isolated through the buffer layer 5, water vapor can be effectively blocked, and corrosion of the metal wires in the drive circuit is prevented.

Exemplarily, a material of the buffer layer 5 may include silicon nitride (SiNx), silicon oxide (SiOx), or a combination thereof. Specifically, silicon nitride (SiNx) has a good water vapor insulating effect, silicon oxide (SiOx) is relatively soft, and the SiNx and the SiOx are very suitable for being prepared on the flexible insulating layer 2.

Exemplarily, as shown in FIG. 2, a projection of a part, arranged over the base substrate 1, of the buffer layer 5 on the base substrate 1 is in the connecting region BB. That is, the buffer layer 5 is not deposited in the display region AA, so that materials are saved and reduction of a thickness of the display panel is facilitated.

Specifically, as shown in FIG. 2, a part, over the connecting region BB of the base substrate 1, of the buffer layer 5 completely covers the first part 21 of the flexible insulating layer 2, so that an edge of the buffer layer 5 and an edge of the first part 21 of the flexible insulating layer 2 form a stepped structure (a part as shown in a dashed box in FIG. 2). Thus, wire breakage caused when the wires come across the edge of the buffer layer 5 and the edge of the flexible insulating layer 2 can be prevented.

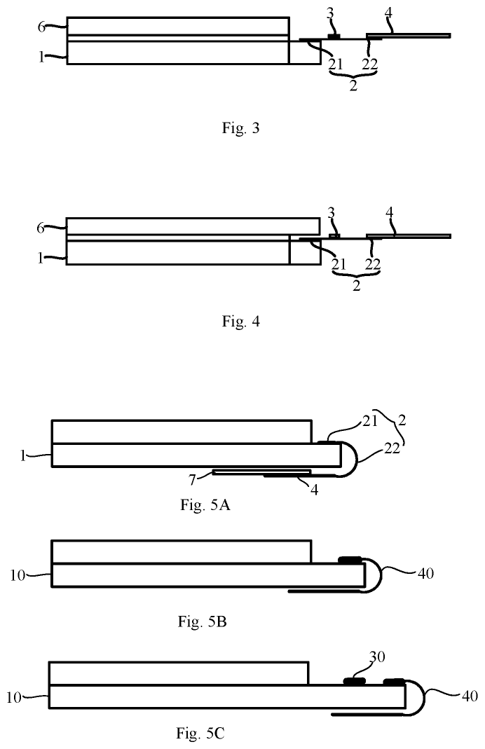

In some embodiments, as shown in FIG. 3 and FIG. 4, the display panel of the embodiments of the present application is a liquid crystal display (LCD), and the base substrate 1 is configured to be a base substrate of an array substrate.

Exemplarily, as shown in FIG. 4, the display panel further includes a color film substrate 6, and a side edge, close to the second part 22 of the flexible insulating layer 2, of the color film substrate 6 is aligned with a side edge, close to the second part 22 of the flexible insulating layer 2, of the base substrate 1, that is, in the LCD, the base substrate 1 and the color film substrate 6 are aligned at a frame edge of a bonding and packaging side.

Existing LCD narrow frame processes all need to perform a bonding process (such as IC and/or FPC bonding) in a frame region of the array substrate, so that edges, on the side of the bonding region, of the color film substrate and the array substrate cannot be aligned, and the color film substrate needs to be cut to expose the bonding region of the array substrate. According to the LCD panel provided by the embodiments of the present application, since the IC 3 and the FPC 4 are bonded on the second part 22 of the flexible insulating layer 2 and the second part 22 exceeds the frame edge of the base substrate 1, part of the frame of the base substrate 1 does not need to be exposed for bonding, and therefore the edges, on the side of the bonding region, of the color film substrate 6 and the array substrate of the display panel of the embodiments of the present application can be aligned, and thus the overall appearance and process of an LCD cell are improved.

Of course, the display panel of the embodiments of the present application may also be designed according to a conventional scheme at present, as shown in FIG. 3 edges, on the side of a bonding region, of a color film substrate 6 and the array substrate are not aligned, and the base substrate 1 of the array substrate exceeds the edge of the color film substrate 6.

In some other embodiments, the display panel of the embodiments of the present application may be a rigid OLED. In this situation, the base substrate is configured to be a base substrate of a drive back plate of the OLED.

In some embodiments, as shown in FIG. 5A, in the display panel of the embodiments of the present application, the second part 22 of the flexible insulating layer 2 is bent to a side, facing away from the first part 21 of the flexible insulating layer 2, of the base substrate 1, so as to be configured to implement packaging of a lower frame of the display panel.

Specifically, embodiments of the present application further provide a display device, and the display device includes the display panel according to any one of the above embodiments.

In some embodiments, as shown in FIG. 5A, the display device of the embodiments of the present application may further include a circuit board 7 located on a side, facing away from a first part 21 of a flexible insulating layer 2, of a base substrate 1. Specifically, a second part 22 of the flexible insulating layer 2 is bent to the side, facing away from the first part 21 of the flexible insulating layer 2, of the base substrate 1, and an FPC 4 bonded on the second part 22 is electrically connected with the circuit board 7. That is, the part, exceeding the base substrate 1, of the flexible insulating layer 2 is configured to be folded and bent to a back surface (one side facing away from a display face) of the display panel for packaging.

Specifically, under the condition that the display device is a liquid crystal display (LCD), the display device is provided with a backlight source, a circuit board is arranged on a side, facing away from the display panel, of the backlight source, and the second part of the flexible insulating layer is bent to a back surface of the backlight source for packaging. Under the condition that the display device is an organic light emitting display (OLED), no backlight source exists, the circuit board is directly disposed on the back surface of the display panel, and the second part of the flexible insulating layer is directly bent to the back surface of the display panel for packaging.

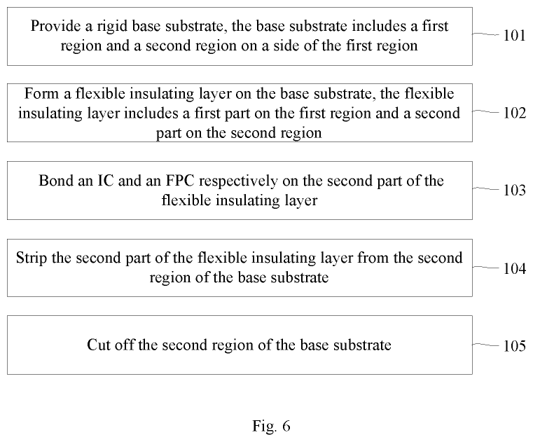

Specifically, based on the display panel provided by the embodiments of the present application, embodiments of the present application further provides a method for preparing a display panel, and as shown in FIG. 6, the method includes the following steps.

Step 101, a rigid base substrate is provided, the base substrate includes a first region and a second region on a side of the first region.

Step 102, a flexible insulating layer is formed on the base substrate, the flexible insulating layer includes a first part on the first region and a second part on the second region.

Step 103, an integrated circuit chip (IC) and a flexible printed circuit (FPC) are respectively bonded on the second part of the flexible insulating layer.

Step 104, the second part of the flexible insulating layer is stripped from the second region of the base substrate.

Step 105, the second region of the base substrate is cut off

Specifically, in the above preparation method, when bonding the IC and the FPC on the flexible insulating layer, since the rigid base substrate is provided under the flexible insulating layer, the process does not have the difficulty of flexible bonding, that is, in the process of pressing the IC or the FPC through a bonding apparatus to perform the bonding connection, crimping between the IC or the FPC and connection terminals can be more easily implemented due to the presence of the rigid base substrate, the yield of crimping is better, and a COG bonding process of a traditional LCD production line can be adopted. Moreover, after the bonding is finished, the second part of the flexible insulating layer is stripped off, and then the stripped base substrate region is cut, so that the first part, which is not stripped, of the flexible insulating layer still has strong bonding force with the base substrate, a COF bonding process can be replaced, and the function of the COF can be replaced with the flexible insulating layer.

According to the display panel formed by the above preparation method, as shown in FIGS. 1 to 4, the flexible insulating layer 2 is disposed on the rigid base substrate 1, the first part 21 of the flexible insulating layer 2 is disposed on the base substrate 1, the second part 22 extends a side edge of the base substrate 1 and is bonded with the IC 3 and the FPC 4, and in the display cell preparation stage, the second part 22 of the flexible insulating layer 2 may be bent to the back surface of the base substrate 1 for packaging, as shown in FIG. 5A, so that a narrow frame of a display cell is realized. Specifically, as shown in FIG. 5A, since a frame region of the base substrate 1 does not need to be bonded with neither an IC nor an FPC, the frame of the display panel can be designed to be very narrow, specifically, the frame of the display panel can be closer to a narrow frame effect of COP (chip on PI) of bonding a chip on a flexible base substrate (PI), and compared with a COF (chip on FPC) scheme of bonding a chip on an FPC 40 as shown in FIG. 5Band a COG (chip on Glass) scheme of bonding a chip 30 on a glass substrate 10 as shown in FIG. 5C, the frame is narrower.

In addition, the above preparation method specifically includes various processes such as flexible film deposition, bonding, flexible film stripping, and base substrate cutting, so that the preparation method is implemented only by adopting part of the process in COG packaging and a simple flexible deposition process, the process is simple, compared with the COF packaging scheme, the defect of COF resource shortage can be avoided, the yield loss problem caused by the COF bonding process can also be avoided, and the practicability is high. Specifically, the preparation method of the display panel can be simultaneously suitable for the rigid OLEDs and the rigid LCDs, so that the rigid OLEDs and the rigid LCDs still have strong competitiveness in the era of full screens.

In some embodiments, a material of the flexible insulating layer 2 may be polyimide (PI); and a material of the base substrate 1 may be glass.

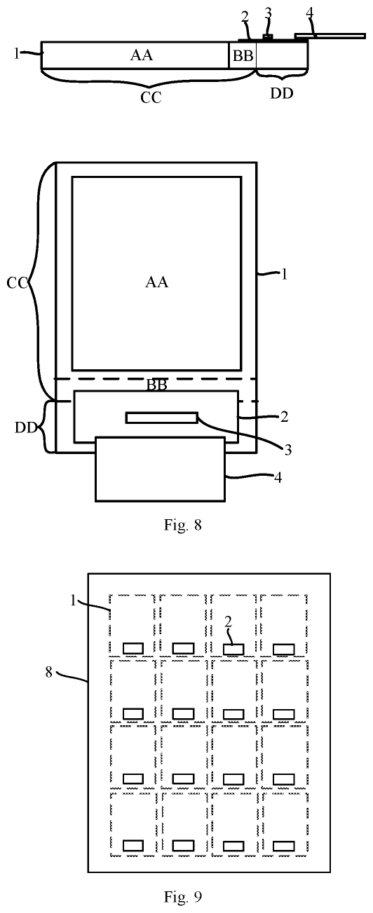

In some embodiments, as shown in FIG. 7 and FIG. 8, a first region CC of the base substrate 1 includes a display region AA and a connecting region BB located between the display region AA and a second region DD. Exemplarily, in step 102, forming the flexible insulating layer 2 on the base substrate 1 may specifically include: forming the flexible insulating layer 2 on the connecting region BB and the second region DD of the base substrate 1. That is, no flexible insulating layer 2 exists on the display region AA of the base substrate 1, and the flexible insulating layer 2 is only disposed on the frame region (the connecting region BB and the second region DD) on a side of the display region AA.

In some embodiments, in step 102, forming the flexible insulating layer 2 on the base substrate 1 may specifically include: forming the flexible insulating layer 2 on the base substrate 1 by adopting a silk-screen printing process.

Specifically, after patterns of the flexible insulating layer 2 are formed by adopting the printing process, the flexible insulating layer 2 may also be subjected to thermal curing treatment.

Specifically, since there is no flexible insulating layer 2 in the display region AA, pixels do not need to be prepared on the flexible insulating layer 2, and only simple signal wires are provided, so that the requirement for the surface of the flexible insulating layer 2 is not high, and the process can be realized through conventional silk-screen printing and other processes.

Therefore, slit coating equipment in a flexible OLED preparation process does not need to be purchased, so that the cost of the scheme is greatly reduced.

In addition, the edge(s) of the flexible insulating layer 2 formed in the silk-screen printing process has/have a certain slope angle, so that wire breakage caused when the wires pass through the junction of edges of a PI film is prevented.

In some embodiments, before step 103, that is, before the IC and the FPC are bonded on the second part of the flexible insulating layer, the method may further include the following step.

As shown in FIG. 7 and FIG. 10, patterns of a drive circuit are formed on the base substrate 1 in an array process.

Specifically, the drive circuit in the embodiments of the present application specifically includes all pattern structures required for implementing pixel driving, including pixel circuits (not shown in figures) within the display region AA, metal wires (not shown in figures) extending to the flexible insulating layer 2, connection terminals located on the second part 22 of the flexible insulating layer 2 used for being bonded the IC and the FPC or the like.

For example, as shown in FIG. 7 and FIG. 10, a connection terminal 31 for being bonded with the IC 3 and a connection terminal 41 for being bonded with the FPC 4 are disposed on the second part 22 of the flexible insulating layer 2.

In some embodiments, before the patterns of the drive circuit are formed on the base substrate in the array process, the method may further include the following step.

As shown in FIG. 2, a buffer layer 5 is formed on the flexible insulating layer 2, and a projection of the buffer layer 5 on the base substrate 1 encompasses a projection of the flexible insulating layer 2 on the base substrate 1.

Specifically, the flexible insulating layer 2 has strong water absorption capacity, the buffer layer 5 is arranged before the drive circuit (including the metal wires) is formed, the flexible insulating layer 2 and a drive circuit layer are isolated through the buffer layer 5, water vapor can be effectively blocked, and corrosion of the metal wires in the drive circuit is prevented.

Exemplarily, a material of the buffer layer 5 may include silicon nitride (SiNx), silicon oxide (SiOx), or a combination thereof. Specifically, silicon nitride (SiNx) has a good water vapor insulating effect, silicon oxide (SiOx) is relatively soft, and the SiNx and the SiOx are very suitable for being prepared on the flexible insulating layer 2.

Exemplarily, as shown in FIG. 2, a projection of a part, arranged over the base substrate 1, of the buffer layer 5 on the base substrate 1 is located in the connecting region BB. That is, the buffer layer 5 is not deposited in the display region AA, so that materials are saved and reduction of a thickness of the display panel is facilitated.

Specifically, as shown in FIG. 2, a part, over the connecting region BB of the base substrate 1, of the buffer layer 5 completely covers the first part 21 of the flexible insulating layer 2, so that an edge of the buffer layer 5 and an edge of the first part 21 of the flexible insulating layer 2 form a stepped structure (a part as shown in a dashed box in FIG. 2). Thus, wire breakage caused when the wires come across the edge of the buffer layer 5 and the edge of the flexible insulating layer 2 can be prevented.

In some embodiments, after the patterns of the drive circuit are formed on the base substrate in the array process, a cell process may also be performed. For example, for the LCD panel, processes such as liquid crystal drop and aligning may be included; and for the OLEDs, processes of depositing a light emitting unit film layer, preparing a packaging layer and the like are included.

In some embodiments, in step 104, stripping the second part of the flexible insulating layer from the second region of the base substrate specifically includes: the second part of the flexible insulating layer is stripped from the second region of the base substrate by adopting a laser lift off (LLO) technology.

In some embodiments, in step 105, cutting off the second region of the base substrate specifically includes:

the base substrate is cut along a boundary line between the first region and the second region from a side, facing away from the flexible insulating layer, of the base substrate, wherein a cutting depth is smaller than a thickness of the base substrate; and after the cutting operation, the first region and the second region of the base substrate are separated along the boundary line by external force, specifically, the base substrate can be directly broken along the boundary line between the first region and the second region. In this way, damage to the flexible insulating layer by the cutting operation can be avoided.

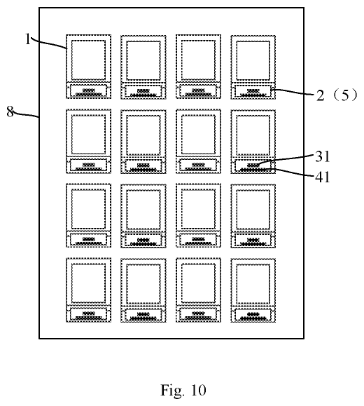

As shown in FIG. 9, in some embodiments, in step 101, providing the rigid base substrate 1 specifically includes: a large-sized substrate 8 is provided, which may include at least two base substrates 1.

Further, before step 103, that is, before the IC and the FPC are bonded on the second part of the flexible insulating layer, the method further includes the following step.

The large-sized substrate 8 is divided by a cutting process to obtain the independent base substrates 1.

Specifically, as shown in FIG. 9 and FIG. 10, part of the cell processes for preparing flexible insulating layers 2, buffer layers 5 and drive circuits (including connection terminals 31 for being bonded with the IC and connection terminals 41 for being bonded with the FPC), and performing liquid crystal aligning or depositing the light emitting unit film layer can be uniformly performed on the basis of the large-sized substrate 8, followed by the division of the large-sized substrate 8, so that independent display cells as shown in FIG. 7 are obtained.

Specifically, in case of the LCD panel, in the substrate cutting process, the edge of the color film substrate may be cut inward to expose the connecting region of the base substrate as in a conventional cutting operation. Since the connecting region does not need a bonding operation, the cutting edge of the color film substrate can be aligned with the cutting edge of the base substrate in the cutting process.

Specifically, after the large-sized substrate is divided by the cutting process to obtain the independent display cells, each display cell is subjected to the bonding process, that is, the IC 3 and the FPC 4 are bonded on the second part 22 of the flexible insulating layer 2 as shown in FIG. 8.

Specifically, as shown in FIG. 8, after bonding of the IC 3 and the FPC 4 is completed, step 104 and step 105 are sequentially performed for each display cell, that is, steps of stripping the second part 22 of the flexible insulating layer 2 and cutting off the second region DD of the base substrate 1 are sequentially performed to obtain the narrow-frame display cell as shown in FIG. 1.

In some embodiments, in step 105, after the second region of the base substrate is cut off, the method further includes the following steps: as shown in FIG. 5A, the second part 22 of the flexible insulating layer 2 is bent to a side, facing away from the first part 21 of the flexible insulating layer 2, of the base substrate 1 for packaging. That is, the part, exceeding the base substrate 1, of the flexible insulating layer 2 is configured to be folded and bent to the back surface (the side facing away from the display surface) of the display panel for packaging.

Specifically, as shown in FIG. 5A, a circuit board 7 is disposed on the side, facing away from the first part 21 of the flexible insulating layer 2, of the base substrate 1. The second part 22 of the flexible insulating layer 2 is bent to the side, facing away from the first part 21 of the flexible insulating layer 2, of the base substrate 1, and the FPC 4 bonded on the second part 22 is electrically connected with the circuit board 7.

Although preferred embodiments of the present application have been described, additional variations and modifications of these embodiments will be made by those skilled in the art upon attaining the basic inventive concept. Therefore, it is intended that the appended claims are interpreted as including the preferred embodiments and all variations and modifications that fall within the scope of the present application.

It will be apparent to those skilled in the art that various changes and variations can be made to the embodiments of the present application without departing from the spirit or scope of the embodiments of the present application. Thus, the present application is also intended to cover the changes and variations of the embodiments provided if they fall within the scope of the appended claims of the present application and their equivalents.

What is claimed is:

1. A display panel, comprising:
a base substrate which is rigid and comprises:
a display region; and
a connecting region on a side of the display region;
a flexible insulating layer disposed on the base substrate and comprising:
a first part; and
a second part;
wherein an orthographic projection of the first part on the base substrate is in the connecting region; and
the second part exceeds a side edge of the connecting region away from the display region;
a buffer layer disposed on and completely covering a surface of a side of the flexible insulating layer facing away from the base substrate; and
a drive circuit, an integrated circuit chip, and a flexible printed circuit disposed on a side of the buffer layer away from the base substrate;
wherein the drive circuit comprises connection terminals for bonding the integrated circuit chip and the flexible printed circuit;
orthographic projections of the connection terminals on the flexible insulating layer are in the second part;
the drive circuit is isolated from the flexible insulating layer through the buffer layer; and
an edge of the buffer layer and an edge of the first part form a stepped structure on the connecting region.

2. The display panel of claim 1, wherein an orthographic projection of the flexible printed circuit on the flexible insulating layer is on a side, away from the first part, of an orthographic projection of the integrated circuit chip on the flexible insulating layer.

3. The display panel of claim 1, wherein the orthographic projection of the integrated circuit chip on the flexible insulating layer is in the second part;
part of the orthographic projection of the flexible printed circuit on the flexible insulating layer is in the second part; and
another part of the orthographic projection of the flexible printed circuit on the flexible insulating layer exceeds a side edge of the second part away from the first part.

4. The display panel of claim 1, wherein:
a width of the connecting region in a direction away from the display region ranges from 200 μm to 400 μm; and
a width of the first part in the direction away from the display region ranges from 200 μm to 300 μm.

5. The display panel of claim 1, wherein an orthographic projection of a part, arranged over the base substrate, of the buffer layer on the base substrate is in the connecting region.

6. The display panel of claim 1, wherein:
a material of the flexible insulating layer is polyimide; and
a material of the base substrate is glass.

7. The display panel of claim 1, further comprising:
a color film substrate;
wherein a side edge, close to the second part, of the color film substrate is aligned with the side edge of the connecting region away from the display region.

8. The display panel of claim 1, wherein the second part is bent to a side, facing away from the first part, of the base substrate.

9. A display device, comprising the display panel according to claim 1.

10. The display device of claim 8, further comprising:
a circuit board on a side, facing away from the first part of the flexible insulating layer, of the base substrate;
wherein the second part of the flexible insulating layer is bent to the side, facing away from the first part of the flexible insulating layer, of the base substrate; and
the integrated circuit chip is electrically connected with the circuit board.

11. A method for preparing the display panel according to claim 1, comprising:
providing the base substrate which is rigid, wherein the base substrate comprises a first region and a second region on a side of the first region;
forming the flexible insulating layer on the base substrate, wherein the flexible insulating layer comprises a first part on the first region and a second part on the second region;
forming the buffer layer on the flexible insulating layer, wherein an orthographic projection of the buffer layer on the base substrate encompasses an orthographic projection of the flexible insulating layer on the base substrate;
forming a pattern of the drive circuit on the buffer layer in an array process;
bonding the integrated circuit chip and the flexible printed circuit on connection terminals of the drive circuit;
stripping the second part of the flexible insulating layer from the second region of the base substrate; and
cutting off the second region of the base substrate.

12. The method of claim 11, wherein the first region comprises the display region and the connecting region, and the connecting region is between the display region and the second region; and
said forming the flexible insulating layer on the base substrate comprises:
forming the flexible insulating layer on the connecting region and the second region of the base substrate.

13. The method of claim 12, wherein said forming the flexible insulating layer on the base substrate comprises:
forming the flexible insulating layer on the base substrate in a silk-screen printing process.

14. The method of claim 11, wherein said stripping the second part of the flexible insulating layer from the second region of the base substrate comprises:
stripping the second part of the flexible insulating layer from the second region of the base substrate by adopting a laser lift off technology.

15. The method of claim 11, wherein said cutting off the second region of the base substrate comprises:
cutting the base substrate along a boundary line between the first region and the second region from a side, facing away from the flexible insulating layer, of the base substrate, wherein a cutting depth is smaller than a thickness of the base substrate; and
separating the first region and the second region of the base substrate along the boundary line by external force.

16. The method of claim 11, wherein after said cutting off the second region of the base substrate, the method further comprises:
bending the second part of the flexible insulating layer to a side, facing away from the first part of the flexible insulating layer, of the base substrate for packaging.
